(19) United States
(12) Patent Application Publication
(10) Pub. No.: US 2024/0365652 A1
(43) Pub. Date: Oct. 31, 2024

(54) TO-BE-EVAPORATED SUBSTRATES, DISPLAY SUBSTRATES AND MANUFACTURING METHODS THEREOF

(71) Applicants: Chengdu BOE Optoelectronics Technology Co., Ltd., Chengdu, Sichuan (CN); BOE Technology Group Co., Ltd., Beijing (CN)

(72) Inventors: Chengjie QIN, Beijing (CN); Hongjun ZHOU, Beijing (CN); Zhuoran YAN, Beijing (CN); Yanwei LU, Beijing (CN); Quan SHI, Beijing (CN); Yudiao CHENG, Beijing (CN); Zhenli ZHOU, Beijing (CN); Fengli JI, Beijing (CN)

(21) Appl. No.: 18/029,883

(22) PCT Filed: May 31, 2022
(86) PCT No.: PCT/CN2022/096205

§ 371 Date: Mar. 31, 2023

(51) Int. Cl. H10K 71/16; C23C 14/04; H10K 59/12; H10K 59/122

(52) U.S. Cl. CPC H10K 71/166; C23C 14/042; H10K 59/1201; H10K 59/122

(57) ABSTRACT

The present disclosure provides a to-be-evaporated substrate, a display substrate and a method of manufacturing a display substrate. The to-be-evaporated substrate may include: a substrate including a to-be-evaporated region and a non-evaporated region, where the non-evaporated region surrounds the to-be-evaporated region; a support pattern, disposed on the substrate and located in the non-evaporated region, where the support pattern includes a plurality of supporters for supporting a mask and further includes a first symmetrical pattern formed by a plurality of supporters, and the plurality of supporters forming the first symmetrical pattern are arranged along a perimeter of the to-be-evaporated region. The present disclosure can improve evaporation effect.

### TECHNICAL FIELD

The present disclosure relates to the field of display technologies, and in particular to a to-be-evaporated substrate, a display substrate and a manufacturing method thereof.

### BACKGROUND

At present, Organic Light-emitting Diode (OLED) display panels are mainly manufactured by evaporation. During an evaporation process, a Fine Metal Mask (FMM) is used to form light-emitting functional layers of sub-pixels, for example, R/G/B sub-pixels or the like, so that a material can be evaporated to a set position. But, the existing evaporation effect is poor.

### SUMMARY

The object of the present disclosure is to provide a to-be-evaporated substrate, a display substrate and a manufacturing method thereof, so as to improve evaporation effect.

According to an aspect of the present disclosure, there is provided a to-be-evaporated substrate, including:

a substrate, including a to-be-evaporated region and a non-evaporated region, where the non-evaporated region surrounds the to-be-evaporated region: and

a support pattern, disposed on the substrate and located in the non-evaporated region, where the support pattern includes a first symmetrical pattern, the first symmetrical pattern is formed by a plurality of supporters, and the plurality of supporters forming the first symmetrical patterns are arranged along a perimeter of the to-be-evaporated region.

In some embodiments, the to-be-evaporated region is presented as a second symmetrical pattern, and a symmetrical axis of the first symmetrical pattern coincides with a symmetrical axis of the second symmetrical pattern.

In some embodiments, the first symmetrical pattern includes two symmetrical axes perpendicular to each other: the to-be-evaporated region is presented as a second symmetrical pattern, the second symmetrical pattern includes two symmetrical axes perpendicular to each other: and the two symmetrical axes of the first symmetrical pattern are respectively coincided with the two symmetrical axes of the second symmetrical pattern.

In some embodiments, the plurality of supporters each include a plurality of support columns arranged in a spacing.

In some embodiments, the number of to-be-evaporated regions is multiple, and at least one of the to-be-evaporated regions respectively includes a plurality of to-be-evaporated sub-regions arranged in a spacing.

In some embodiments, the at least one of the to-be-evaporated regions respectively includes two to-be-evaporated sub-regions arranged in a spacing, the two to-be-evaporated sub-regions are arranged symmetrically, and a symmetrical axis of the two to-be-evaporated sub-regions coincides with a symmetrical axis of the first symmetrical pattern.

In some embodiments, the at least one of the to-be-evaporated regions respectively includes two to-be-evaporated sub-regions arranged in a spacing, the two to-be-evaporated sub-regions are presented as two symmetrical patterns, symmetrical axes of two to-be-evaporated sub-regions in one of the at least one of the to-be-evaporated regions coincide with each other, and the symmetrical axes of the to-be-evaporated sub-regions coincide with a symmetrical axis of the first symmetrical pattern.

In some embodiments, the plurality of to-be-evaporated sub-regions in one of at least one of the to-be-evaporated regions are used to evaporate a same evaporation material.

In some embodiments, the number of to-be-evaporated regions is multiple, and the number of first symmetrical patterns is multiple, the to-be-evaporated regions are in one-to-one correspondence with the first symmetrical patterns, and two of the first symmetrical patterns share at least one of the supporters.

In some embodiments, two to-be-evaporated regions corresponding to the two first symmetrical patterns sharing at least one of the supporters are used to evaporate a same evaporation material or different evaporation materials.

In some embodiments, the supporters each include a support layer and a plurality of protrusions, the support layer is disposed on the substrate, and the plurality of protrusions are disposed on a side of the support layer away from the substrate, and the plurality of protrusions are arranged in a spacing.

In some embodiments, the substrate includes:

a base:

a pixel definition layer, disposed on a side of the base, where the pixel definition layer includes one or more pixel openings:

where the to-be-evaporated region includes one or more to-be-evaporated sub-regions, and the pixel opening forms the to-be-evaporated sub-region.

According to an aspect of the present disclosure, there is provided a display substrate, including:

the to-be-evaporated substrate:

a light emitter, disposed in the to-be-evaporated region.

According to an aspect of the present disclosure, there is provided a method of manufacturing a display substrate, including:

preparing a mask and the to-be-evaporated substrate:

forming a light emitter by performing evaporation on the to-be-evaporated region using the mask.

For a to-be-evaporated substrate, a display substrate and a method of manufacturing a display substrate in the present disclosure, when a film layer is formed by evaporation process, a mask is supported by a support pattern. A plurality of supporters in the support pattern are arranged along a perimeter of a to-be-evaporated region and further form a first symmetrical pattern, so as to improve support uniformity, helping to improve the thickness uniformity of the film layer formed by evaporation as well as evaporation effect.

### BRIEF DESCRIPTION OF THE DRAWINGS

FIGS. 1 to 6 are schematic diagrams illustrating a to-be-evaporated substrate according to an embodiment of the present disclosure.

FIG. 7 is a partial view of the structure shown in FIG. 5.

FIG. 8 is a partial view of the structure shown in FIG. 6.

FIGS. 9 to 12 are schematic diagrams illustrating a to-be-evaporated substrate according to other embodiments of the present disclosure.

FIGS. 13 to 14 are sectional schematic diagrams illustrating a to-be-evaporated substrate according to an embodiment of the present disclosure.

Numerals of the drawings are described below: 1 to-be-evaporated region; 1A first-type to-be-evaporated region; 1B second-type to-be-evaporated region; 1C third-type to-be-evaporated region; 101 to-be-evaporated sub-region; 2 non-evaporated region; 3 supporter; 301 support column; 302 support layer; 303 protrusion; 4 base; 5 drive circuit layer; 6 planarization layer; 7 pixel definition layer; 701 pixel opening; 100 first symmetrical pattern.

### DETAILED DESCRIPTION OF THE EMBODIMENTS

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

Terms used herein are used to only describe a particular embodiment rather than limit the present disclosure. Unless otherwise defined, technical terms or scientific terms used in the present disclosure should have general meanings that can be understood by ordinary persons of skill in the art. “First” “second” or the like used in the specification and claims do not represent any sequence, quantity or importance, but distinguish different components. Similarly, “one” or “a” or the like do not represent quantity limitation, but represent at least one. “Multiple” or “a plurality” represents two or more. Unless otherwise stated, the words such as “front”, “rear”, “lower” and/or “upper” are used only for ease of descriptions rather than limited to one position or a spatial orientation. Unless otherwise stated, “include” or “contain” or the like is intended to refer to that an element or object appearing before “include” or “contain” covers an element or object or its equivalents listed after “include” or “contain” and does not preclude other elements or objects. “Connect” or “connect with” or the like is not limited to physical or mechanical connection but includes direct or indirect electrical connection. The singular forms such as “a”, “said”, and “the” used in the present disclosure and the appended claims are also intended to include plural forms, unless the context clearly indicates otherwise. It is also to be understood that the term “and/or” as used herein refers to and includes any or all possible combinations of one or more associated listed items.

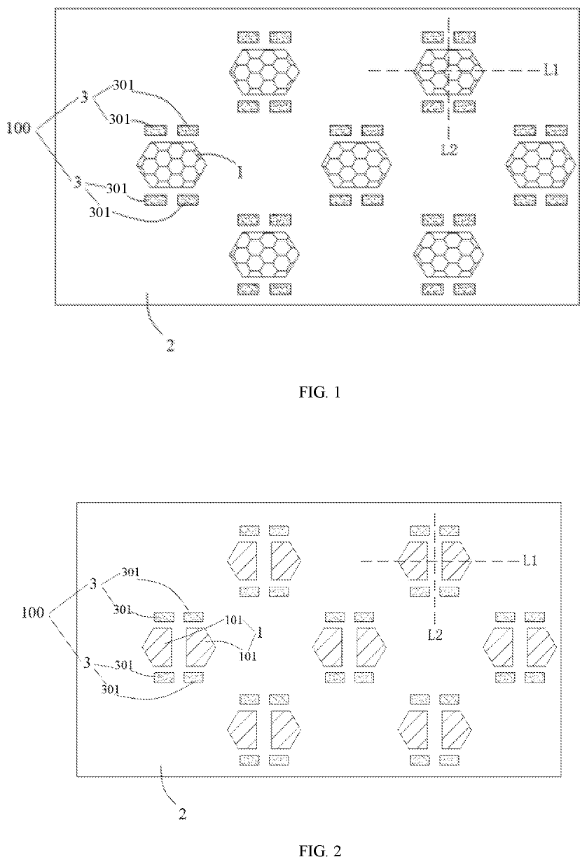

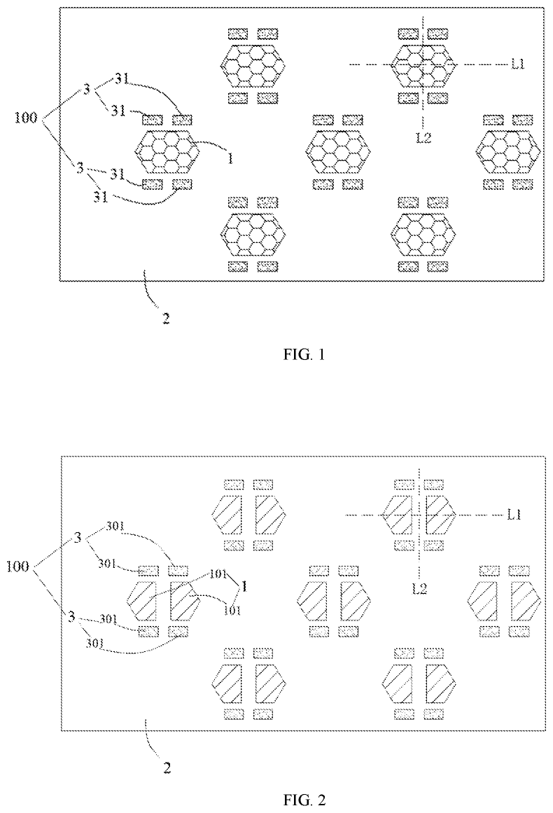

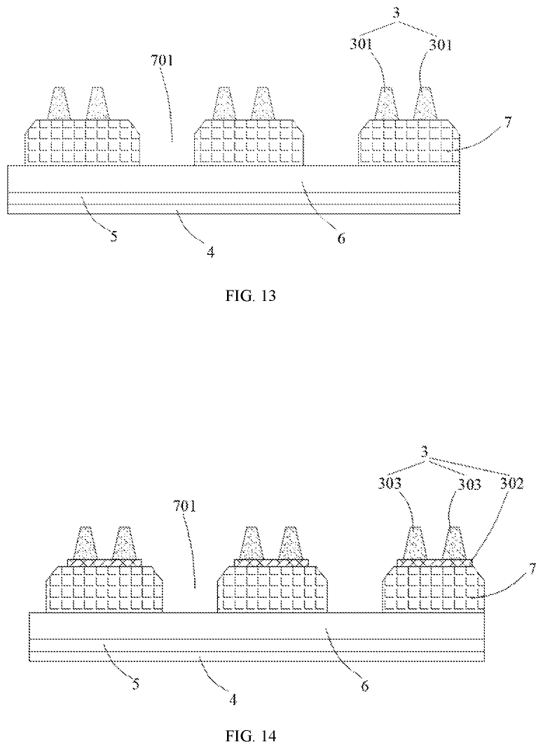

The present disclosure provides a to-be-evaporated substrate, which is used to manufacture a display substrate or the like. As shown in FIGS. 1 and 13, the to-be-evaporated substrate may include a substrate and a support pattern.

As shown in FIG. 1, the substrate may include one or more to-be-evaporated regions 1 and a non-evaporated region 2. The non-evaporated region 2 surrounds the one or more to-be-evaporated regions 1. The support pattern is disposed on the substrate and located in the non-evaporated region 2. The support pattern includes a plurality of supporters 3 for supporting a mask. The support pattern may include one or more first symmetrical patterns 100. The first symmetrical pattern 100 is formed by a plurality of supporters 3, and the plurality of supporters 3 forming the first symmetrical pattern 100 are arranged along a perimeter of the to-be-evaporated region 1.

In the to-be-evaporated substrate of the present disclosure, when a film layer is formed by evaporation process, the support pattern is configured to support the mask. A plurality of supporters 3 in the support pattern are arranged along a perimeter of the to-be-evaporated regions 1, and further form the first symmetrical patterns 100, so as to improve support uniformity, helping to improve the thickness uniformity of the film layer formed by evaporation as well as evaporation effect.

The parts of the to-be-evaporated substrate will be further elaborated below in combination with specific embodiments.

If the to-be-evaporated substrate is used to manufacture a display substrate, the substrate may include a base 4 and a pixel definition layer 7 as shown in FIG. 13. The base 4 may be a rigid base, where the rigid base may be a glass base or a Polymethyl methacrylate (PMMA) base or the like. In some embodiments, the base 4 may be a flexible base, where the flexible base may be a Polyethylene terephthalate (PET) base, or a Polyethylene naphthalate two formic acid glycol ester (PEN) base or a Polyimide (PI) base.

The pixel definition layer 7 may be disposed on the base 4. In some embodiments, the substrate may further include a drive circuit layer 5 and a planarization layer 6. The drive circuit layer 5 may be disposed on the base 4. The drive circuit layer 5 may include a plurality of drive transistors. The drive transistors may be thin film transistors, which is not limited in the embodiments. The thin film transistor may be a top-gate thin film transistor. In some embodiments, the thin film transistor may be a bottom-gate thin film transistor. With the thin film transistor as the top-gate thin film transistor, the drive circuit layer 5 may include an active layer, a gate insulation layer, a gate electrode, an interlayer insulation layer, a source electrode and a drain electrode. The active layer may be disposed on the base 4. The gate insulation layer may be disposed on the base 4 and covered on the active layer. The gate electrode may be disposed on a side of the gate insulation layer away from the base 4. The interlayer insulation layer may be disposed on the gate insulation layer and covered on the gate electrode. The source electrode and the drain electrode may be disposed on the interlayer insulation layer and connected to the active layer through via holes penetrating through the interlayer insulation layer and the gate insulation layer. The planarization layer 6 may be disposed on a surface of the drive circuit layer 5 away from the base 4 and covered on the source electrode and the drain electrode of the drive transistor. The pixel definition layer 7 may be disposed on the planarization layer 6. The pixel definition layer 7 may include one or more pixel openings 701. The one or more pixel openings 701 may include a plurality of pixel openings arranged in an array. The pixel opening 701 may be a tetragon, a pentagon or a hexagon or the like, which is not limited herein. In some embodiments, the pixel openings 701 may be used to evaporate a light-emitting material. The plurality of pixel openings 701 may include a first-type pixel opening, a second-type pixel opening and a third-type pixel opening.

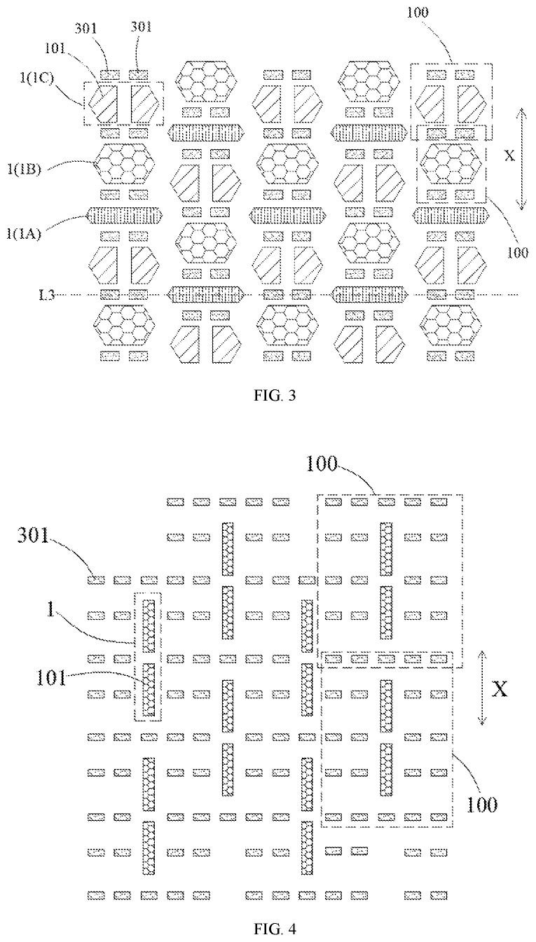

As shown in FIG. 1, the substrate may include one or more to-be-evaporated regions 1 and a non-evaporated region 2. The number of the one or more to-be-evaporated regions 1 may be one. In some embodiments, the number of the one or more to-be-evaporated regions 1 may be multiple, and the plurality of to-be-evaporated regions are arranged in a spacing. The non-evaporated region 2 surrounds the to-be-evaporated regions 1. In an embodiment of the present disclosure, as shown in FIG. 1, one to-be-evaporated region 1 may only include one to-be-evaporated sub-region 101. In another embodiment of the present disclosure, as shown in FIG. 2, one to-be-evaporated region 1 may include a plurality of to-be-evaporated sub-regions 101 arranged in a spacing. For example, one to-be-evaporated region 1 may include two to-be-evaporated sub-regions 101 arranged in a spacing. In other embodiments of the present disclosure, as shown in FIG. 3, the substrate may include a plurality of to-be-evaporated regions 1, where at least one of the plurality of to-be-evaporated regions 1 only includes one to-be-evaporated sub-region 1 respectively, and at least one of the plurality of to-be-evaporated regions 1 may respectively include two to-be-evaporated sub-regions 101 arranged in a spacing. A region of the pixel definition layer 7 in one pixel opening 701 may form one to-be-evaporated sub-region 101. The to-be-evaporated sub-region 101 may be used to evaporate a desired evaporation material which may be a light-emitting material, for example, a red light-emitting material, a green light-emitting material or a blue light-emitting material. A plurality of to-be-evaporated sub-regions 101 in one to-be-evaporated region 1 may be used to evaporate a same evaporation material, or different evaporation materials.

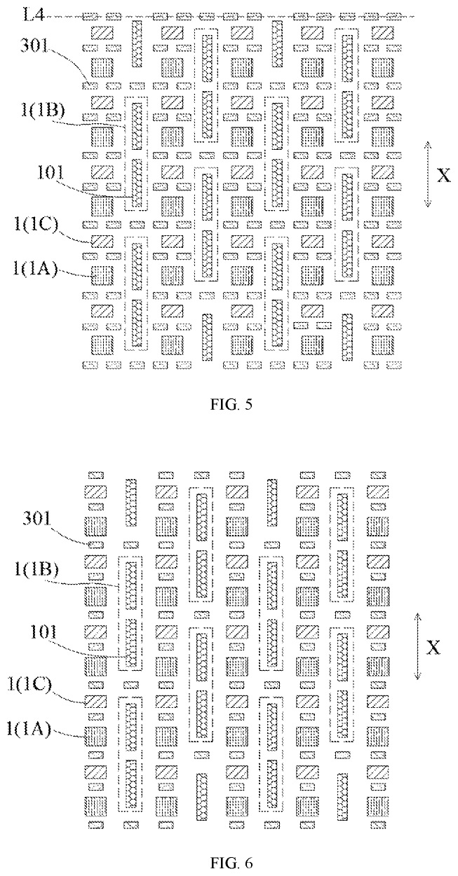

For example, as shown in FIGS. 3, 5, 6, and 9 to 12, a plurality of to-be-evaporated regions 1 may include a first-type to-be-evaporated region 1A, a second-type to-be-evaporated region 1B, and a third-type to-be-evaporated region 1C. A plurality of first-type to-be-evaporated regions 1A, a plurality of second-type to-be-evaporated regions 1B and a plurality of third-type to-be-evaporated regions 1C are provided. The plurality of first-type to-be-evaporated regions 1A are arranged in an array, the plurality of second-type to-be-evaporated regions 1B are arranged in an array and the plurality of third-type to-be-evaporated regions 1C are arranged in an array. The first-type to-be-evaporated regions 1A are used to evaporate a red light-emitting material, the second-type to-be-evaporated regions 1B are used to evaporate a blue light-emitting material, and the third-type to-be-evaporated regions 1C are used to evaporate a green light-emitting material. In FIG. 3, the third-type to-be-evaporated region 1C includes two to-be-evaporated sub-regions 101. In FIGS. 5 and 6, the second-type to-be-evaporated region 1B includes two to-be-evaporated sub-regions 101.

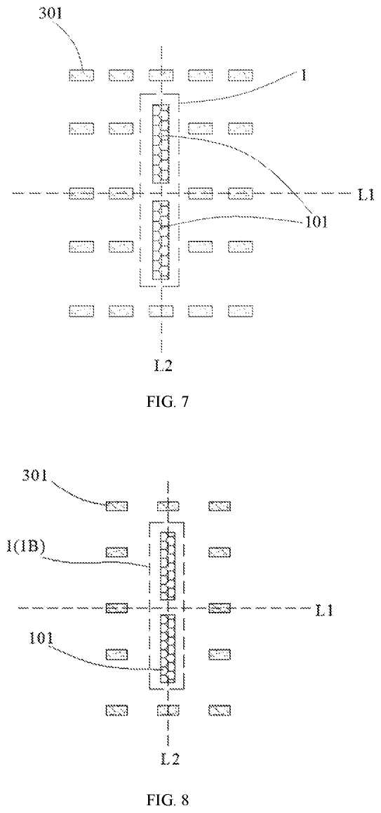

The to-be-evaporated region 1 may be presented as a second symmetrical pattern, and a symmetrical axis of the second symmetrical pattern may be parallel to the to-be-evaporated substrate. As shown in FIG. 1, for example, one to-be-evaporated region 1 only includes one to-be-evaporated sub-region 101 and the pixel opening 701 forms the to-be-evaporated sub-region 101. In this case, one to-be-evaporated sub-region 101 may be presented as a second symmetrical pattern (a symmetrical axis is L1 or L2 in FIG. 1) in the present disclosure. That is, one pixel opening 701 is presented as a second symmetrical pattern, such that the to-be-evaporated region 1 including one to-be-evaporated sub-region 101 is presented as a second symmetrical pattern. As shown in FIGS. 2, 7 and 8, for example, one to-be-evaporated region 1 includes two to-be-evaporated sub-regions 101 and two pixel openings 701 form the two to-be-evaporated sub-regions 101. In this case, the two to-be-evaporated sub-regions 101 may be arranged symmetrically (a symmetrical axis is L2 in FIG. 2) in the present disclosure. That is, the two pixel openings 701 corresponding to the two to-be-evaporated sub-regions 101 are arranged symmetrically, such that the to-be-evaporated region 1 including two to-be-evaporated sub-regions 101 is presented as a second symmetrical pattern. In other embodiments of the present disclosure, as shown in FIGS. 2, 7 and 8, the two to-be-evaporated sub-regions 101 may be presented as two axisymmetric patterns, and symmetrical axes of the two to-be-evaporated sub-regions 101 coincide with each other (the symmetrical axes each are L1 in FIG. 2). That is, the two pixel openings 701 may be presented as two axisymmetric patterns, and symmetrical axes of the two pixel openings 701 coincide with each other, such that the to-be-evaporated region 1 including two to-be-evaporated sub-regions 101 is presented as a second symmetrical pattern.

As shown in FIGS. 1, 2, 7 and 8, the second symmetrical pattern may include two symmetrical axes which are perpendicular to each other (two symmetrical axes are L1 and L2). For example, one to-be-evaporated region 1 includes two to-be-evaporated sub-regions 101. In this case, each of the two to-be-evaporated sub-regions 101 is presented as a axisymmetric pattern, and symmetrical axes of the two to-be-evaporated sub-regions 101 coincide with each other and meanwhile, the two to-be-evaporated sub-regions 101 are further symmetrically arranged. Thus, the second symmetrical pattern includes two symmetrical axes perpendicular to each other.

The support pattern is disposed on the substrate and located in the non-evaporated region 2. In some embodiments, the support pattern may be disposed in a region of the pixel definition layer 7 outside the pixel openings 701. The support pattern may include a plurality of supporters 3. The supporters 3 are configured to support a mask used in an evaporation process. As shown in FIGS. 1 and 2, the support pattern may include one or more first symmetrical patterns 100, the symmetrical axis of the first symmetrical pattern 100 may be parallel to the to-be-evaporated substrate. The first symmetrical pattern 100 is formed by a plurality of supporters 3 which are arranged along a perimeter of the to-be-evaporated region 1, so as to improve support uniformity. In some embodiments, the first symmetrical pattern 100 may include two symmetrical axes, where the two symmetrical axes may be perpendicular to each other and parallel to the to-be-evaporated substrate.

As shown in FIGS. 1 and 2, the symmetrical axis of the first symmetrical pattern 100 may coincide with the symmetrical axis of the second symmetrical pattern. In some embodiments, for example, the first symmetrical pattern 100 and the second symmetrical pattern include two symmetrical axes respectively, and the two symmetrical axes of the first symmetrical pattern 100 are respectively coincided with the two symmetrical axes of the second symmetrical pattern (the two symmetrical axes of the first symmetrical pattern 100 also are L1 and L2). “Two symmetrical axes coincide with each other” in the present disclosure refers to the two symmetrical axes are in a same straight line.

As shown in FIGS. 3 to 6, if a plurality of to-be-evaporated regions 1 and a plurality of first symmetrical patterns 100 are disposed, the plurality of first symmetrical patterns 100 may be in one-to-one correspondence with the plurality of to-be-evaporated regions 1, and two of the plurality of first symmetrical patterns 100 share at least one of the supporters 3, thus reducing the number of the supporters 3 and saving the costs. As shown in FIGS. 3 to 6, symmetrical axes of a plurality of to-be-evaporated regions 1 arranged along an X direction are in a same straight line. As shown in FIGS. 3 and 4, two adjacent first symmetrical patterns 100 arranged along the X direction share at least one of the supporters 3. In FIG. 3, two to-be-evaporated regions 1 corresponding to two first symmetrical patterns 100 sharing at least one of the supporters 3 are used to evaporate different evaporation materials. In FIG. 4. two to-be-evaporated regions 1 corresponding to two first symmetrical patterns 100 sharing at least one of the supporters 3 are used to evaporate a same evaporation material.

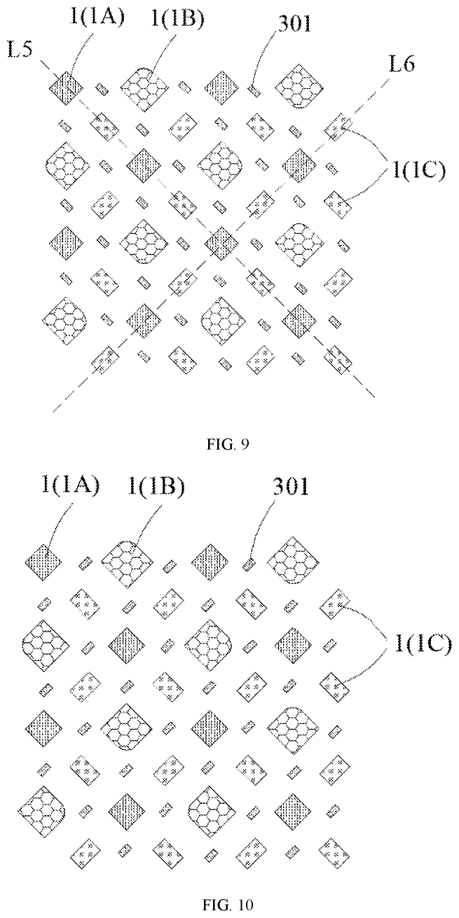

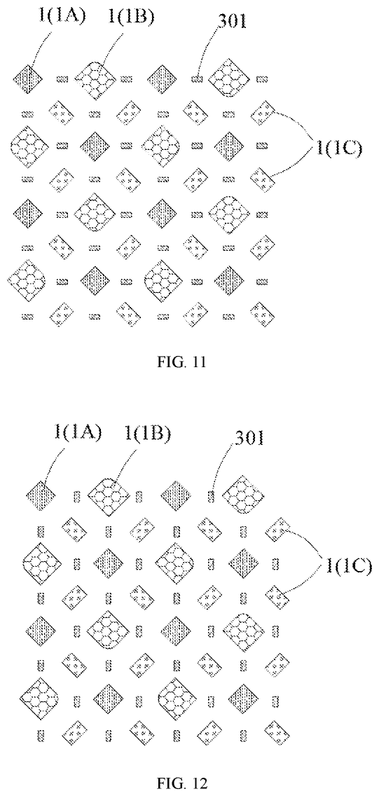

In some embodiments, in FIG. 3, a straight line L3 is perpendicular to the X direction. Centers of a plurality of support columns 301 arranged along an extension direction of the straight line L3 are all located on the straight line L3, and centers of a plurality of to-be-evaporated regions 1 arranged along the extension direction of the straight line L3 are located on the straight line L3. In FIG. 5, a straight line L4 is perpendicular to the X direction, and centers of a plurality of support columns 301 arranged along an extension direction of the straight line L4 are all located on the straight line L4. In FIG. 9, centers of a plurality of to-be-evaporated regions 1 arranged along an extension direction of a straight line L5 are located on the straight line L5, and centers of a plurality of to-be-evaporated regions 1 arranged along an extension direction of a straight line L6 are located on the straight line L6, where the straight line L5 is perpendicular to the straight line L6. In some embodiments, the support columns 301 located on both sides of the straight line L5 are arranged symmetrically with the straight line L5 as symmetrical axis, and the to-be-evaporated regions 1 located on both sides of the straight line L5 are arranged symmetrically with the straight line L5 as symmetrical axis. The support columns 301 located on both sides of the straight line L6 are arranged symmetrically with the straight line L6 as symmetrical axis, and the to-be-evaporated regions 1 located on both sides of the straight line L6 are arranged symmetrically with the straight line L6 as symmetrical axis. Compared with FIG. 9, the support columns 301 in FIG. 10 rotate 90° clockwise around the centers of the support columns 301; compared with FIG. 10, the support columns 301 in FIG. 11 rotate 45° clockwise around the centers of the support columns 301; compared with FIG. 11, the support columns 301 in FIG. 12 rotate 90° clockwise around the centers of the support columns 301.

In some embodiments, one supporter 3 in the present disclosure may only include one support column 301, which can be called original support column in the present disclosure. As shown in FIG. 13, in the present disclosure, the original support column may be replaced with a plurality of spaced-apart support columns 301 with smaller cross sectional area. Compared with the original support column, these support columns 301 with smaller cross sectional area can reduce a frictional force between the support columns 301 and the mask and reduce foreign matters produced by scratching between the mask and the support columns 301, thereby increasing the product yield and extending the product life. In other embodiments of the present disclosure, as shown in FIG. 14, the supporter 3 may include a support layer 302 and a plurality of protrusions 303. The support layer 302 may be disposed in a region of the pixel definition layer 7 outside the pixel opening 701. The plurality of protrusions 303 are disposed on a side of the support layer 302 away from the base, and the plurality of protrusions 303 are arranged in a spacing. The protrusion 303 has a smaller cross sectional area than the original support column, so that foreign matters produced by scratching between the mask and the support columns 301 can further be reduced.

An embodiment of the present disclosure further provides a display substrate, which may include a light emitter and the to-be-evaporated substrate mentioned in any one of the above embodiments. The light emitter may be disposed in the to-be-evaporated region 1. In some embodiments, the light emitter may be disposed in the above to-be-evaporated sub-region 101.

An embodiment of the present disclosure further provides a method of manufacturing a display substrate. The method may include: preparing a mask and the to-be-evaporated substrate mentioned in any one of the above embodiments; forming a light emitter by performing evaporation on the to-be-evaporated region 1 using the mask.

The to-be-evaporated substrate, the display substrate and the method of manufacturing a display substrate in the present disclosure all belong to a same concept, and their relevant details and beneficial effects can be referred to each other. Therefore, no redundant descriptions are made herein.

The above descriptions are made merely to preferred embodiments of the present disclosure rather than intended to limit the present disclosure in any manner. Although the present disclosure is made with preferred embodiments as above, these preferred embodiments are not used to limit the present disclosure. Those skilled in the art may make some changes or modifications to the technical contents of the present disclosure as equivalent embodiments without departing from the scope of the technical solution of the present disclosure. Any simple changes, equivalent changes or modifications made to the above embodiments based on the technical essence of the present disclosure without departing from the contents of the technical solution of the present disclosure shall all fall within the scope of protection of the present disclosure.

1. A to-be-evaporated substrate, comprising:
a substrate, comprising a to-be-evaporated region and a non-evaporated region, wherein the non-evaporated region surrounds the to-be-evaporated region; and
a support pattern, disposed on the substrate and located in the non-evaporated region, wherein,
the support pattern comprises a first symmetrical pattern,
the first symmetrical pattern is formed by a plurality of supporters, and
the plurality of supporters forming the first symmetrical pattern are arranged along a perimeter of the to-be-evaporated region.

2. The to-be-evaporated substrate of claim 1, wherein,
the to-be-evaporated region is presented as a second symmetrical pattern, and
a symmetrical axis of the first symmetrical pattern coincides with a symmetrical axis of the second symmetrical pattern.

3. The to-be-evaporated substrate of claim 1, wherein,
the first symmetrical pattern comprises two symmetrical axes perpendicular to each other;
the to-be-evaporated region is presented as a second symmetrical pattern, the second symmetrical pattern comprises two symmetrical axes perpendicular to each other; and
the two symmetrical axes of the first symmetrical pattern are respectively coincided with the two symmetrical axes of the second symmetrical pattern.

4. The to-be-evaporated substrate of claim 1, wherein the plurality of supporters each comprise a plurality of support columns arranged in a spacing.

5. The to-be-evaporated substrate of claim 1, wherein,
the number of to-be-evaporated regions is multiple, and
at least one of the to-be-evaporated regions respectively comprises a plurality of to-be-evaporated sub-regions arranged in a spacing.

6. The to-be-evaporated substrate of claim 5, wherein,
the at least one of the to-be-evaporated regions respectively comprises two to-be-evaporated sub-regions arranged in a spacing,
the two to-be-evaporated sub-regions are arranged symmetrically, and
a symmetrical axis of the two to-be-evaporated sub-regions coincides with a symmetrical axis of the first symmetrical pattern.

7. The to-be-evaporated substrate of claim 5, wherein,
the at least one of the to-be-evaporated regions respectively comprises two to-be-evaporated sub-regions arranged in a spacing,
the two to-be-evaporated sub-regions are presented as two symmetrical patterns,
symmetrical axes of two to-be-evaporated sub-regions in one of the at least one of the to-be-evaporated regions coincide with each other, and the symmetrical axes of the to-be-evaporated sub-regions coincide with a symmetrical axis of the first symmetrical pattern.

8. The to-be-evaporated substrate of claim 5, wherein the plurality of to-be-evaporated sub-regions in one of at least one of the to-be-evaporated regions are used to evaporate a same evaporation material.

9. The to-be-evaporated substrate of claim 1, wherein,
the number of to-be-evaporated regions is multiple, and the number of first symmetrical patterns is multiple,
the to-be-evaporated regions are in one-to-one correspondence with the first symmetrical patterns, and
two of the first symmetrical patterns share at least one of the supporters.

10. The to-be-evaporated substrate of claim 9, wherein two to-be-evaporated regions corresponding to the two first symmetrical patterns sharing at least one of the supporters are used to evaporate a same evaporation material or different evaporation materials.

11. The to-be-evaporated substrate of claim 1, wherein,
the supporters each comprise a support layer and a plurality of protrusions,
the support layer is disposed on the substrate,
the plurality of protrusions are disposed on a side of the support layer away from the substrate, and
the plurality of protrusions are arranged in a spacing.

12. The to-be-evaporated substrate of claim 1, wherein the substrate comprises:
a base;
a pixel definition layer, disposed on a side of the base, wherein the pixel definition layer comprises one or more pixel openings;
wherein the to-be-evaporated region comprises one or more to-be-evaporated sub-regions, and the pixel opening forms the to-be-evaporated sub-region.

13. A display substrate, comprising:
the to-be-evaporated substrate of claim 1;
a light emitter, disposed in the to-be-evaporated region.

14. A method of manufacturing a display substrate, comprising:
preparing a mask and a to-be-evaporated substrate, wherein the to-be-evaporated substrate comprises:
a substrate, comprising a to-be-evaporated region and a non-evaporated region, wherein the non-evaporated region surrounds the to-be-evaporated region; and
a support pattern, disposed on the substrate and located in the non-evaporated region, wherein,
the support pattern comprises a first symmetrical pattern,
the first symmetrical pattern is formed by a plurality of supporters, and
the plurality of supporters forming the first symmetrical pattern are arranged along a perimeter of the to-be-evaporated region;
forming a light emitter by performing evaporation on the to-be-evaporated region using the mask.
